(19) United States
(12) Patent Application Publication
(10) Pub. No.: US 2003/0003667 A1
(43) Pub. Date: Jan. 2, 2003

(54) Semiconductor device and method of fabricating the same

(75) Inventors: Yusuke Morisaki, Kawasaki (JP); Yoshihiro Sugita, Kawasaki (JP); Kiyoshi Irino, Kawasaki (JP)

Correspondence Address: ARMSTRONG,WESTERMAN & HATTORI, LLP, 1725 K STREET, NW., SUITE 1000, WASHINGTON, DC, 20006, US

(73) Assignee: Fujitsu Limited, Kawasaki (JP)

(21) Appl. No.: 10/151,168

(22) Filed: May 21, 2002

(30) Foreign Application Priority Data
Jun. 22, 2001 (JP) 2001-190145

(51) Int. Cl. H01L 21/336

(52) U.S. Cl. 438/287

(57) ABSTRACT

A method includes the steps of forming a gate insulating film on a monocrystalline silicon substrate, forming a conductive film on the gate insulating film, and processing at least the conductive film to form a gate electrode. The gate insulating film is made up from an aluminum oxide film about 1 nm thick deposited on the monocrystalline silicon substrate by CVD, a hafnium oxide film about 4 nm thick deposited on the aluminum oxide film by CVD, and another aluminum oxide film about 1 nm thick deposited on the hafnium oxide film by CVD under the same formation conditions as the former aluminum oxide film.

### CROSS-REFERENCE TO RELATED APPLICATIONS

This application is based upon and claims priority of Japanese Patent Application No. 2001-190145, filed on Jun. 22, 2001, the contents being incorporated herein by reference.

### BACKGROUND OF THE INVENTION

1. Field of the Invention

The present invention relates to a semiconductor device and a method of fabricating the same and, more particularly, to a semiconductor device suitably used as a MIS transistor and a method of fabricating the same.

2. Description of the Related Art

In conventional MIS devices, a silicon oxide film is used as a gate insulating film because the film is stable in the fabrication process and a good insulating film is obtained with relative ease.

On the other hand, with the recent increasing accuracy of the transistor characteristics of devices, it is being required to decrease the electrical thickness (a thickness converted into a film thickness of a predetermined insulating film (e.g., a silicon oxide film); to be referred to as a “converted film thickness” hereinafter) of a gate insulating film. If, however, a physical film thickness (actual film thickness) is decreased to decrease the converted film thickness, a serious problem that a leakage current increases owing to a tunnel effect inevitably arises.

It is, therefore, possible to solve the above problem by using a material having a dielectric constant higher than that of a silicon oxide film as a gate insulating film, thereby decreasing the converted film thickness while increasing the physical film thickness.

J. G. Simmons revealed in Journal of Applied Physics (1963, Vol. 34, p. 1793) that a leakage current flowing in an insulating film by a tunnel effect is given by

$$Jg = \frac{{q}^{2} ( {φ}_{B} - q {V}_{OX} / 2 )}{2 π h {t}_{OX}^{2}} exp [ \frac{- 4 π {t}_{OX} \sqrt{{2}_{{qm}^{*}} ( {φ}_{B} - q {V}_{OX} / 2 )}}{h} ] \qquad ( 1 )$$

q: charge elementary quantity

h: Planck's constant

φ_{B}: barrier height

V_{OX}: applied voltage

t_{OX}: insulating film thickness

m*: effective mass of electron

According to the above equation, to suppress the leakage current, it is necessary to take into account not only the contribution of the insulating film thickness (physical film thickness) t_{OX} but also the contribution of the barrier height φ_{B}. That is, if this barrier height φ_{B} lowers, the leakage current (leakage current density Jg) increases.

FIG. 6 shows the characteristics of the gate voltage Vg [V] and the leakage current density Jg [A/m²] of a plurality of barrier heights φ_{B} [eV]. As shown in FIG. 6, the leakage current density Jg increases as the barrier height φ_{B} decreases.

The barrier height φ_{B} is determined by the combination of a gate insulating film material and a semiconductor material. The higher the dielectric constant of a material, the lower the barrier height between the conduction band of the material and the conduction band of a semiconductor material (particularly silicon).

That is, even when the physical film thickness is increased by using a material having a dielectric constant higher than that of a silicon oxide film as a gate insulating film, the barrier height lowers. As a consequence, a leakage current caused by a tunnel effect cannot be effectively reduced.

### SUMMARY OF THE INVENTION

The present invention has been made in consideration of the above situation, and has as its object to provide a semiconductor device capable of decreasing the converted film thickness while increasing the physical film thickness by using a material having a dielectric constant higher than that of a silicon oxide film as a gate insulating film, and also capable of effectively reducing a leakage current caused by a tunneling effect by suppressing a lowering of the barrier height, and to provide a method of fabricating the same.

The present inventors made extensive studies and have reached various modes of the present invention presented below.

The present invention has as its fabrication object a semiconductor device including a gate electrode formed over a semiconductor substrate with a gate insulating film being interposed between them. The physical film thickness is increased by using a material having a relatively high dielectric constant as the gate insulating film. In addition, lowering the barrier height with respect to the semiconductor material is prevented by using a material having a relatively low dielectric constant on one or both of the semiconductor-substrate-side surface and the gate-electrode-side surface of the material having a relatively high dielectric constant.

That is, a method of fabricating a semiconductor device comprises the steps of forming a gate insulating film on a semiconductor substrate, forming a conductive film on the gate insulating film, and processing at least the conductive film to form a gate electrode, wherein the gate insulating film is formed by a first insulating film and a second insulating film which is formed on at least one of a semiconductor-substrate-side surface and a gate-electrode-side surface of the first insulating film, and made of a material having a dielectric constant lower than that of the first insulating film, and the second insulating film exists all over the first insulating film, or, the gate insulating film is formed by changing its composition such that a dielectric constant gradually lowers toward at least one of a semiconductor-substrate-side surface and a gate-electrode-side surface of the gate insulating film.

In the present invention as described above, a material having a relatively high dielectric constant, such as titanium oxide, zirconium oxide, tantalum oxide, or hafnium oxide, is used as a gate insulating film, and a material having a relatively low dielectric constant, such as silicon oxide, silicon oxynitride, silicon nitride, or aluminum oxide, is used on at least one of the semiconductor-substrate-side surface and the gate-electrode-side surface of the material having a relatively high dielectric constant. This can increase the physical film thickness while decreasing the converted film thickness, and can also prevent lowering the barrier height with respect to the semiconductor material such as silicon. Accordingly, it is possible to decrease the converted film thickness and effectively reduce a leakage current caused by a tunnel effect in the gate insulating film at the same time.

### BRIEF DESCRIPTION OF THE DRAWINGS

FIGS. 1A to 1E are schematic sectional views showing a method of fabricating a semiconductor device in order of steps;

FIGS. 2A to 2C are schematic sectional views showing gate insulating film formation steps in the first embodiment;

FIGS. 3A to 3C are schematic sectional views showing gate insulating film formation steps in the second embodiment;

FIG. 4 is a view showing the values of a relative dielectric constant k, a conduction band discontinuous value Vc, and a forbidden band width difference Vb of insulating materials;

FIG. 5 is a graph showing the characteristics of the relative dielectric constant and the band discontinuous value; and

FIG. 6 is a graph showing the characteristics of a gate voltage Vg and a leakage current density Jg of a plurality of barrier heights φ_{B}.

### DETAILED DESCRIPTION OF THE PREFERRED EMBODIMENTS

Embodiments of a semiconductor device and a method of fabricating the same according to the present invention will be described below with reference to the accompanying drawings. In these embodiments, a MIS transistor is taken as an example of the semiconductor device, and the arrangement of this transistor will be explained along with its fabrication method for the sake of convenience.

(First Embodiment)

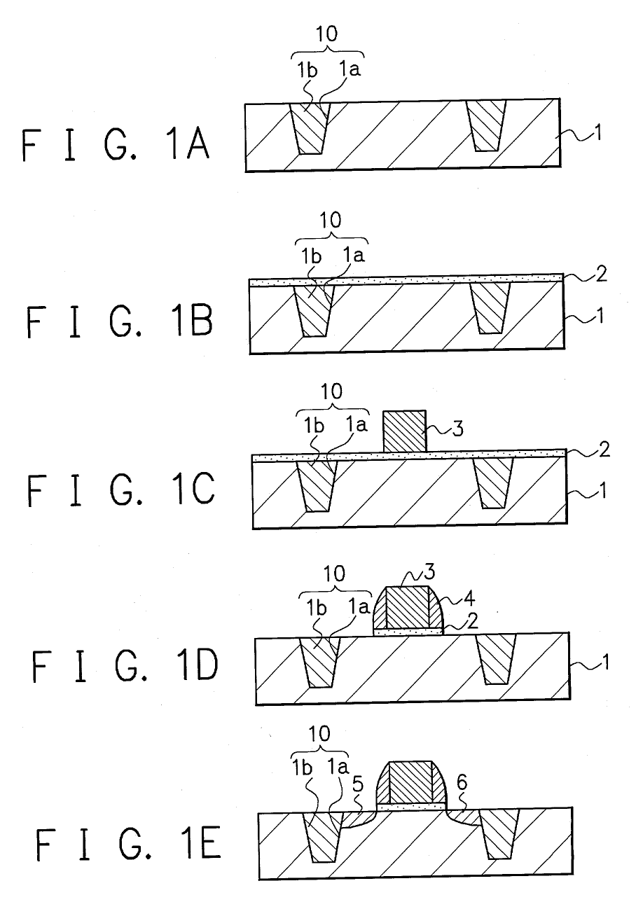

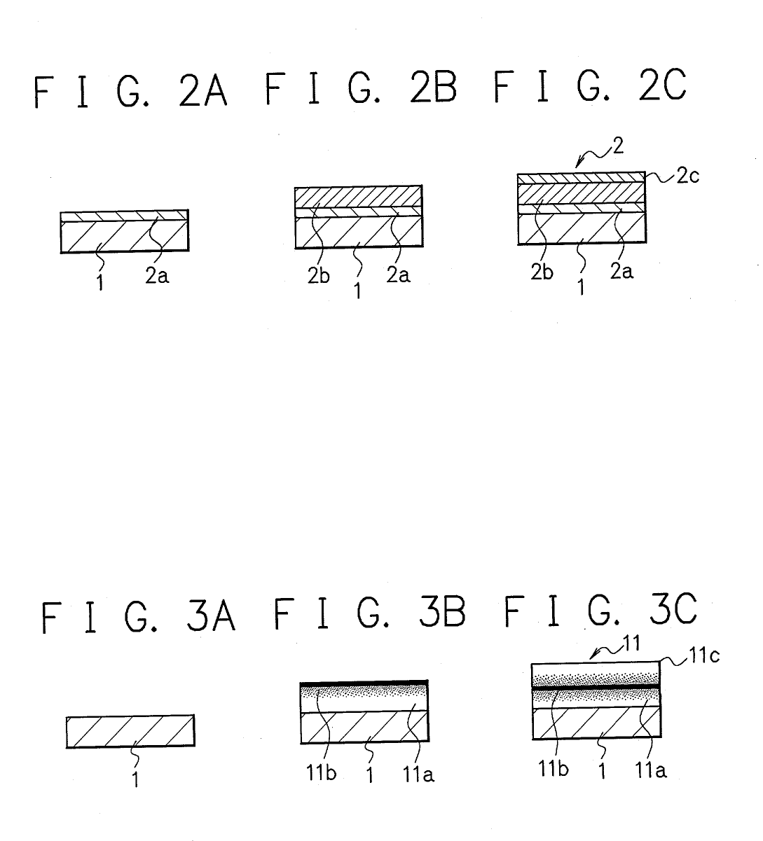

FIGS. 1A to 2C are schematic sectional views showing a method of fabricating a MIS transistor of the first embodiment in order of steps.

First, as shown in FIG. 1A, an element active region is defined in a monocrystalline silicon substrate 1. More specifically, a trench la is formed in an element isolation region of the monocrystalline silicon substrate 1, and an insulator (e.g., SiO₂) 1b is deposited to have a film thickness with which this trench 1a is filled. After that, the insulator 1b on the monocrystalline silicon substrate 1 is removed by CMP (Chemical-Mechanical Polishing), forming an STI (Shallow Trench Isolation) element isolation structure 10 in which the trench la is filled with the insulator 1b. Note that a field oxide film can also be formed by a so-called LOCOS process in place of the STI element isolation structure.

Next, as shown in FIG. 1B, a gate insulating film 2 is formed on the monocrystalline silicon substrate 1. In this embodiment, as will be described below, this gate insulating film 2 has a three-layered structure; the gate insulating film 2 is formed by using an insulating film having a high dielectric constant as an inner layer, and insulating films having a dielectric constant lower than that of the inner layer as outer layers vertically sandwiching this inner layer. Steps of forming the gate insulating film 2 in this embodiment will be explained below with reference to FIGS. 2A to 2C.

First, as shown in FIG. 2A, after a natural oxide film (not shown) formed on the surface of the monocrystalline silicon substrate 1 is removed, an aluminum oxide film 2a about 1 nm thick is deposited on this monocrystalline silicon substrate 1 by CVD. This aluminum oxide film 2a is deposited by introducing gasified trimethyl aluminum and water as materials into a film formation chamber (not shown) by using nitrogen gas.

Next, as shown in FIG. 2B, a hafnium oxide film 2b about 4 nm thick is deposited on the aluminum oxide film 2a by CVD. This hafnium oxide film 2b is deposited by introducing hafnium tetrachloride sublimated by heating and gasified water as materials into the film formation chamber (not shown) by using nitrogen gas.

After that, as shown in FIG. 2C, an aluminum oxide film 2c about 1 nm thick is deposited on the hafnium oxide film 2b by CVD. This aluminum oxide film 2c is deposited under the same formation conditions as the aluminum oxide film 2a formed on the monocrystalline silicon substrate 1.

In this embodiment as described above, the gate insulating film 2 is formed by a three-layered structure in which the hafnium oxide film 2b having a high dielectric constant is sandwiched by the aluminum oxide films 2a and 2c having a dielectric constant lower than that of the hafnium oxide film 2b. Since the MIS structure of this embodiment is not used as a memory element, the aluminum oxide films 2a and 2c are formed all over the hafnium oxide film 2b, i.e., the gate insulating film 2 has entirely a three-layered structure.

After the gate insulating film 2 is formed as described above, as shown in FIG. 1C, polysilicon, a mixed crystal of polysilicon and germanium, or the like is deposited on this gate insulating film 2 and patterned by photolithography and subsequent RIE to form a gate electrode 3 having a predetermined shape (e.g., a band). Although not explained in this embodiment, when the source and drain of the transistor are to be formed to have an LDD (Lightly Doped Drain) structure, ion implantation is performed at a relatively low density and a low acceleration energy after the formation of the gate electrode 3.

Furthermore, as shown in FIG. 1D, a silicon oxide film, a silicon nitride film, or an insulating film combining the both is deposited (not shown). The entire surface of this insulating film is anisotropically etched (etched back) by RIE to leave the insulating film only on the side surfaces of the gate electrode 3, forming side walls 4.

Also, that portion of the gate insulating film 2 on the monocrystalline silicon substrate 1, which is exposed to the surface is removed. This gate insulating film 2 can be removed by RIE. However, if the removal by RIE is insufficient, the gate insulating film 2 can also be removed by plasma etching.

Subsequently, as shown in FIG. 1E, the gate electrode 3 and the side walls 4 are used as masks to implant, into the element active region, ions having a conductivity type opposite to that of the substrate 1. Activation annealing is then performed to form the source 5 and drain 6.

After that, although not shown, post-treatments such as the formation of a dielectric interlayer, a contact hole, and a predetermined wiring layer are performed to complete the MIS transistor of this embodiment.

In the first embodiment described above, the gate insulating film 2 has a three-layered structure (Al₂O₃—HfO₂—Al₂O₃) in which the aluminum oxide films 2a and 2c having a large barrier height are formed on the two surfaces of the hafnium oxide film 2b having a relatively high dielectric constant. Therefore, it is possible to increase the physical film thickness (actual film thickness) while decreasing the electrical film thickness (a thickness converted into a film thickness of a predetermined insulating film (e.g., a silicon oxide film); to be referred to as a “converted film thickness” hereinafter) of a gate insulating film. In addition, lowering the barrier height with respect to silicon forming the substrate 1 and the gate electrode 3 can be prevented. Accordingly, the gate insulating film 2 by which a leakage current caused by a tunnel effect is suppressed can be formed while the converted film thickness is decreased. This makes it possible to provide a high-performance semiconductor device.

(Second Embodiment)

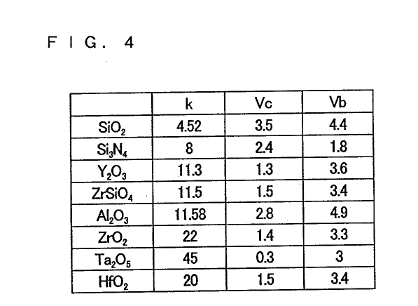

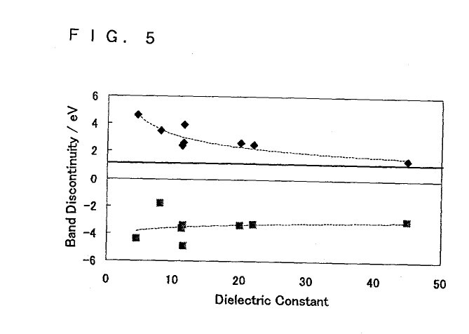

In the second embodiment, an example in which the composition of a gate insulating film 11 is continuously changed will be explained. Steps of forming the gate insulating film 11 in this embodiment will be described below with reference to FIGS. 3A to 3C. The rest of the steps are the same as explained in FIGS. 1A to 1E, so a detailed description thereof will be omitted.

In this embodiment, the gate insulating film 11 is formed by changing its composition such that the dielectric constant gradually lowers toward a monocrystalline silicon substrate 1 and a gate electrode 3.

First, a natural oxide film (not shown) formed on the surface of the monocrystalline silicon substrate 1 is removed. After that, as shown in FIGS. 3A to 3C, the gate insulating film 11 is formed by CVD by controlling the supply amounts of trimethyl aluminum, hafnium tetrachloride, and water as materials.

That is, when the formation of the gate insulating film is started (the state shown in FIG. 3A), the gate insulating film 11 is deposited by decreasing the supply amount of hafnium tetrachloride and increasing the supply amount of trimethyl aluminum (the state shown in FIG. 3B). Consequently, a portion 11a of this gate insulating film 11, which is made of an oxide mixture of hafnium oxide and a large amount of aluminum oxide, is formed on the monocrystalline silicon substrate 1. In this portion 11a, lowering the barrier height with respect to the monocrystalline silicon substrate 1 can be prevented because the large amount of aluminum oxide is contained.

Subsequently, the gate insulating film 11 is deposited by gradually decreasing the supply amount of trimethyl aluminum and increasing the supply amount of hafnium tetrachloride (the state shown in FIG. 3B). Consequently, a portion 11b of this gate insulating film 11, which is made of an oxide mixture of aluminum oxide and a large amount of hafnium oxide, is formed on the portion 11a. In this portion 11b, the physical film thickness can be increased because the large amount of hafnium oxide is contained.

After that, the gate insulating film 11 is deposited by again decreasing the supply amount of hafnium tetrachloride and increasing the supply amount of trimethyl aluminum, thereby completing the formation of the gate insulating film 11 (the state shown in FIG. 3C). As a consequence, a portion 11c of this gate insulating film 11, which is made of an oxide mixture of hafnium oxide and a large amount of aluminum oxide, is formed on the portion 11b. In this portion 11c, lowering the barrier height with respect to a gate electrode 3 to be formed later can be prevented because the large amount of aluminum oxide is contained.

In the second embodiment described above, the gate insulating film 11 has a structure (Al₂O₃—HfO₂—Al₂O₃) in which the composition is continuously changed from the central portion 11b toward the two surfaces such that this central portion 11b containing hafnium oxide having a relatively high dielectric constant gradually becomes the portions 11a and 11c containing aluminum oxide having a large barrier height. Therefore, the physical film thickness (actual film thickness) can be increased while the converted film thickness is decreased. In addition, lowering the barrier height with respect to silicon forming the substrate 1 and the gate electrode 3 can be prevented. Accordingly, it is possible to form the gate insulating film 11 by which a leakage current caused by a tunnel effect is suppressed while the converted film thickness is reduced. This makes it possible to provide a high-performance semiconductor device.

Also, at the start of the film formation, during the inner film formation, and at the end of the film formation, the supply amounts of trimethyl aluminum and hafnium tetrachloride need only be changed, i.e., neither supply source need be completely stopped.

In the above first and second embodiments, the gate insulating films 2 and 11 are formed using hafnium oxide (HfO₂) and aluminum oxide (Al₂O₃) having a lower dielectric constant (i.e., a larger barrier height) than that of the hafnium oxide. However, this combination is merely an example and does not restrict the invention.

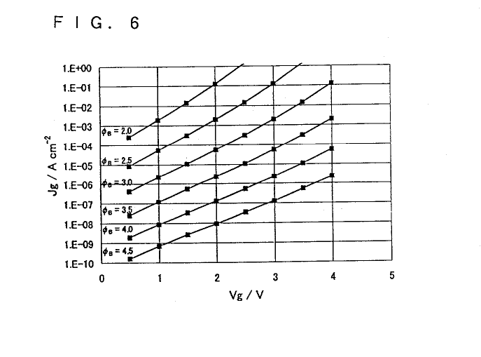

FIG. 4 shows the values of a specific dielectric constant k, a conduction band discontinuous value Vc (barrier height) [eV], and a forbidden band width difference Vb [eV] of various insulating materials supposed to be usable as a gate insulating film in a semiconductor device. FIG. 5 shows the characteristics of the specific dielectric constant and the band discontinuous value [eV].

Basically, a gate electrode need only be formed using a material having a large specific dielectric constant k and a material having a small specific dielectric constant (i.e., a large barrier height). For example, in the above first and second embodiments, an aluminum oxide (Al₂O₃) is explained as a low-dielectric-constant material. However, it is also possible to use this aluminum oxide (Al₂O₃) as a high-dielectric-constant material and form, on the two surfaces of this aluminum oxide, silicon oxide (SiO₂), silicon oxynitride (SiON), or silicon nitride (Si₃N₄) having a lower dielectric constant (i.e., a larger barrier height) than that of the aluminum oxide.

Especially when a metal oxide having a very large specific dielectric constant k, such as zirconium oxide (ZrO₂), tantalum oxide (Ta₂O₅), or hafnium oxide (HfO₂) shown in FIG. 4 is used, the physical film thickness can be increased while the converted film thickness is decreased accordingly. In this case, aluminum oxide (Al₂O₃), silicon oxide (SiO₂), or the like having a lower dielectric constant (a smaller specific dielectric constant k) than those of ZrO₂, Ta₂O₅, and HfO₂ need only be formed on the two surfaces.

In the above first and second embodiments, HfO₂ is used because ZrO₂ has low thermal stability (the phase transition temperature is as relatively low as about 1,000° C.) and Ta₂O₅ has an extremely low conduction band discontinuous value Vc [eV] although its specific dielectric constant k is very large. That is, HfO₂ has relatively high thermal stability compared with ZrO₂. Although the specific dielectric constant k of HfO₂ is smaller than that of Ta₂O₅, it is much larger than that of, e.g., SiO₂ commonly used as a gate insulating film. Also, the conduction band discontinuous value Vc [eV] of HfO₂ does not extremely lower.

In the embodiments described above, a material having a relatively low dielectric constant is used on the two surfaces of the gate insulating films 2 and 11, i.e., on the sides of monocrystalline silicon substrate 1 and the gate electrode 3. However, the effect of suppressing a leakage current caused by a tunnel effect is obtained by the use of this low-dielectric-constant material on at least one surface. Conversely, it is also possible to form a multilayer structure including a larger number of layers than in the three-layered structure described in the first embodiment.

When, however, a p-channel FET and an n-channel FET are to be formed on the same substrate, it is necessary to stabilize their operations with symmetry. As explained in the first and second embodiments, therefore, it is desirable to equalize the formation conditions of the two sides (the aluminum oxide films 2a and 2c in the first embodiment, and the portions 11a and 11c in the second embodiment) of the gate insulating films 2 and 11.

The present invention makes it possible to form a gate insulating film by which a leakage current caused by a tunnel effect is suppressed while the converted film thickness is decreased. This can realize a high-performance semiconductor device.

What is claimed is:

1. A method of fabricating a semiconductor device, comprising the steps of:
forming a gate insulating film on a semiconductor substrate;
forming a conductive film on said gate insulating film; and
processing at least said conductive film to form a gate electrode,
wherein said gate insulating film is formed by a first insulating film and a second insulating film which formed on at least one of a semiconductor-substrate-side surface and a gate-electrode-side surface of said first insulating film, and made of a material having a dielectric constant lower than that of said first insulating film, and said second insulating film exists all over said first insulating film.

2. The method according to claim 1, wherein said second insulating film is formed on both of said semiconductor-substrate-side surface and said gate-electrode-side surface of said first insulating film.

3. The method according to claim 1, wherein said first insulating film is made of metal oxide.

4. The method according to claim 3, wherein said metal oxide is one member or a mixture of a plurality of members selected from the group consisting of titanium oxide, zirconium oxide, tantalum oxide, and hafnium oxide.

5. The method according to claim 4, wherein said second insulating film is made of a material selected from the group consisting of silicon oxide, silicon oxynitride, silicon nitride, and aluminum oxide.

6. The method according to claim 3, wherein said metal oxide is aluminum oxide, and said second insulating film is made of a material selected from the group consisting of silicon oxide, silicon oxynitride, and silicon nitride.

7. A method of fabricating a semiconductor device, comprising the steps of:
forming a gate insulating film on a semiconductor substrate;
forming a conductive film on said gate insulating film; and
processing at least said conductive film to form a gate electrode,
wherein said gate insulating film is formed by changing a composition thereof such that a dielectric constant gradually lowers toward at least one of a semiconductor-substrate-side surface and a gate-electrode-side surface of said gate insulating film.

8. The method according to claim 7, wherein said composition is changed such that said dielectric constant gradually lowers toward both of said semiconductor-substrate-side surface and said gate-electrode-side surface of said first insulating film.

9. The method according to claim 7, wherein said insulating film contains metal oxide.

10. The method according to claim 9, wherein said metal oxide is one member or a mixture of a plurality of members selected from the group consisting of titanium oxide, zirconium oxide, tantalum oxide, and hafnium oxide.

11. The method according to claim 10, wherein said composition is changed by adding a material selected from the group consisting of silicon oxide, silicon oxynitride, silicon nitride, and aluminum oxide, such that said dielectric constant lowers.

12. The method according to claim 9, wherein said metal oxide is aluminum oxide, and said composition is changed by adding a material selected from the group consisting of silicon oxide, silicon oxynitride, and silicon nitride, such that said dielectric constant lowers.

13. The method according to claim 7, wherein said gate insulating film is formed by CVD, and the supply amount of a material is changed during the film formation.

14. A semiconductor device comprising:
a semiconductor substrate;
a gate insulating film formed on said semiconductor substrate; and
a gate electrode formed on said gate insulating film and processed into a predetermined shape,
wherein said gate insulating film is formed by a first insulating film and a second insulating film which is formed on at least one of a semiconductor-substrate-side surface and a gate-electrode-side surface of said first insulating film, and made of a material having a dielectric constant lower than that of said first insulating film, and said second insulating film exists all over said first insulating film.

15. The device according to claim 14, wherein said second insulating film is formed on both of said semiconductor-substrate-side surface and said gate-electrode-side surface of said first insulating film.

16. The device according to claim 14, wherein said first insulating film is made of metal oxide.

17. The device according to claim 16, wherein said metal oxide is one member or a mixture of a plurality of members selected from the group consisting of titanium oxide, zirconium oxide, tantalum oxide, and hafnium oxide.

18. The device according to claim 17, wherein said second insulating film is made of a material selected from the group consisting of silicon oxide, silicon oxynitride, silicon nitride, and aluminum oxide.

19. The device according to claim 16, wherein said metal oxide is aluminum oxide, and said second insulating film is made of a material selected from the group consisting of silicon oxide, silicon oxynitride, and silicon nitride.

20. A semiconductor device comprising:
a semiconductor substrate;
a gate insulating film formed on said semiconductor substrate; and
a gate electrode formed on said gate insulating film and processed into a predetermined shape,
wherein said gate insulating film is formed by changing a composition thereof such that a dielectric constant gradually lowers toward at least one of a semiconductor-substrate-side surface and a gate-electrode-side surface of said gate insulating film.

21. The device according to claim 20, wherein said composition is changed such that said dielectric constant gradually lowers toward both of said semiconductor-substrate-side surface and said gate-electrode-side surface of said insulating film.

22. The device according to claim 20, wherein said insulating film contains metal oxide.

23. The device according to claim 22, wherein said metal oxide is one member or a mixture of a plurality of members selected from the group consisting of titanium oxide, zirconium oxide, tantalum oxide, and hafnium oxide.

24. The device according to claim 23, wherein said composition is changed by adding a material selected from the group consisting of silicon oxide, silicon oxynitride, silicon nitride, and aluminum oxide, such that said dielectric constant lowers.

25. The device according to claim 22, wherein said metal oxide is aluminum oxide, and said composition is changed by adding a material selected from the group consisting of silicon oxide, silicon oxynitride, and silicon nitride, such that said dielectric constant lowers.

26. A semiconductor device comprising:
a semiconductor substrate;
a gate insulating film formed on said semiconductor substrate; and
a gate electrode formed on said gate insulating film and processed into a predetermined shape,
wherein said gate insulating film is formed by a high-dielectric-constant film and an insulating film which is formed on at least one of a semiconductor-substrate-side surface and a gate-electrode-side surface of said high-dielectric-constant film, and made of a material having a barrier height larger than that of said high-dielectric-constant film.

27. A semiconductor device comprising:
a semiconductor substrate;
a gate insulating film formed on said semiconductor substrate; and
a gate electrode formed on said gate insulating film and processed into a predetermined shape,
wherein said gate insulating film is formed by changing a composition thereof such that a barrier height gradually increases toward at least one of a semiconductor-substrate-side surface and a gate-electrode-side surface of said gate insulating film.
